(19) United States
(12) Patent Application Publication
(10) Pub. No.: US 2016/0084901 A1
(43) Pub. Date: Mar. 24, 2016

(54) APPARATUS OF INSPECTING RESISTIVE DEFECTS OF SEMICONDUCTOR DEVICES AND INSPECTING METHOD USING THE SAME

(71) Applicant: Samsung Electronics Co., Ltd., Suwon-si (KR)

(72) Inventors: Mi-Ra PARK, Suwon-si (KR); Dae-Jin SUNG, Suwon-si (KR); Yu-Sin YANG, Seoul (KR); Na-Kyoung LEE, Seoul (KR); Sang-Kil LEE, Yongin-si (KR); Chung-Sam JUN, Suwon-si (KR); Yong-Deok JEONG, Hwaseong-si (KR)

(21) Appl. No.: 14/677,173

(22) Filed: Apr. 2, 2015

(30) Foreign Application Priority Data
Sep. 19, 2014 (KR) 10-2014-0125232

(51) Int. Cl. G01R 31/265

(52) U.S. Cl. CPC G01R 31/2653

(57) ABSTRACT

A method of inspecting a resistive defect of a semiconductor device is provided. The method includes loading a semiconductor wafer on a wafer stocker, transferring the semiconductor wafer into a laser anneal module, annealing a portion of the semiconductor wafer using a laser beam in an atmospheric pressure, transferring the annealed semiconductor wafer into an E-beam scanning module in a vacuum, scanning the annealed portions of the semiconductor wafer with an E-beam, and collecting secondary electrons emitted from the annealed portions of the semiconductor wafer.

### CROSS-REFERENCE TO RELATED APPLICATION

This application claims priority under 35 U.S.C. §119 to Korean Patent Application No. 10-2014-0125232 filed on Sep. 19, 2014 in the Korean Intellectual Property Office (KIPO), the contents of which are herein incorporated by reference in their entirety.

### BACKGROUND

1. Technical Field

Embodiments of the inventive concepts relate to an apparatus for inspecting a resistive defect of a semiconductor device, in particular a resistive defect of contact plug patterns, and a method of inspecting a resistive defect of a semiconductor device using the apparatus.

2. Description of Related Art

As sizes of circuit patterns of semiconductor devices are reduced, a process of inspecting resistance values of contact plug patterns has become a very important process. Accordingly, not only a process of inspecting whether contact-hole patterns are open or not, but also a process of inspecting resistive defects, that is, determining whether the formed contact plug patterns have an appropriate resistance or not, has become required. Normally, there is a method of inspecting resistive defects by measuring resistances of contact plug patterns using a probe or the like, configured to be in contact with the contact plug patterns or pad patterns connected to the contact plug patterns. However, since sizes of contact plug patterns have become reduced, it has become difficult to inspect the contact plug patterns using a scanning electron microscope (SEM). Further, reliability of a result of the inspection has been significantly decreased.

### SUMMARY

Some embodiments of the inventive concepts provide a method of inspecting a resistive defect of a semiconductor device.

Some other embodiments of the inventive concepts provide a method of inspecting a contact plug pattern of a semiconductor device.

Still other embodiments of the inventive concepts provide an apparatus for inspecting a resistive defect of a semiconductor device.

Still other embodiments of the inventive concepts provide an apparatus for inspecting a contact plug pattern of a semiconductor device.

In one embodiment, a method of inspecting a resistive defect of a semiconductor device includes loading a semiconductor wafer on a wafer stocker, transferring the semiconductor wafer into an laser anneal module using a transfer module, annealing a portion of the semiconductor wafer using a laser beam in an atmospheric-pressure, transferring the annealed semiconductor wafer into an E-beam scanning module using the transfer module in a vacuum, scanning the annealed portions of the semiconductor wafer with an E-beam, and collecting secondary electrons emitted from the annealed portions of the semiconductor water.

In accordance with another embodiment, a method of inspecting a resistive defect of a semiconductor device includes providing a semiconductor wafer including contact plug patterns, locally annealing portions of the semiconductor wafer to crystallize the contact plug patterns therein, scanning the crystallized contact plug patterns with an E-beam, and collecting secondary electrons emitted from the contact plug patterns scanned with the E-beam.

In accordance with still another embodiment, a method of inspecting a resistive defect of a semiconductor device includes providing an inspecting apparatus including a wafer stocker, a transfer module, an annealing module, a buffer chamber, and an E-beam scanning module, loading a semiconductor wafer including contact plug patterns on the wafer stocker, transferring the semiconductor wafer into the annealing module using a transfer arm of the transfer module, locally annealing portions of the semiconductor wafer in the annealing module to crystallize the contact plug patterns, transferring the semiconductor wafer into the buffer chamber, evacuating the buffer chamber, transferring the semiconductor wafer disposed in the buffer chamber into the E-beam scanning module, scanning the locally-crystallized contact plug patterns of the semiconductor wafer with an E-beam in the E-beam scanning module, collecting secondary electrons from the locally-crystallized contact plug patterns, and displaying a gray-scale image of the contact plug patterns on a monitor according to the amount of the collected secondary electrons.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference numerals denote the same respective parts throughout the different views. The drawings are not necessarily to scale, emphasis instead being placed upon illustrating the principles of the inventive concepts. In the drawings:

FIGS. 1A to 1E are block diagrams schematically illustrating inspecting apparatuses according to various embodiments;

FIG. 2 is a diagram schematically illustrating a laser anneal module of an inspecting apparatus according to an embodiment;

FIG. 3 is a diagram schematically illustrating an E-beam scanning module of an inspecting apparatus according to an embodiment;

FIG. 4 is a flowchart for describing a method of inspecting resistive defects of contact plug patterns of a semiconductor device according to an embodiment;

FIGS. 5A to 5E are diagrams for describing a method of inspecting resistive defects of contact plug patterns of a semiconductor device according to an embodiment; and

FIGS. 6A and 6B are a diagram and a SEM photograph illustrating secondary electrons E2 emitted from contact plug patterns which are not laser-annealed, and FIGS. 7A and 7B are a diagram and a SEM photograph illustrating secondary electrons E2 emitted from laser-annealed contact plug patterns.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. The embodiments of the invention are only provided for complete disclosure of the invention and to fully show the scope of the invention to those skilled in the art, and only defined by the scope of the appended claims.

The terminology used herein to describe embodiments of the invention is not intended to limit the scope of the invention. The use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof

It will be understood that when an element is referred to as being “connected to” or “coupled to” another element, it can be connected or coupled to the other element or intervening elements may be present. In contrast, when an element is referred to as “directly connected to” or “directly coupled to” another element or layer, there are no intervening elements or layers present. The term “and/or” includes any and all combinations of one or more referents.

Spatially relative terms, such as “beneath,” “below,” “lower,” “above,” “upper,” and the like may be used herein to describe the relationship of one element or feature to another, as illustrated in the drawings. It will be understood that such descriptions are intended to encompass different orientations in use or operation in addition to orientations depicted in the drawings.

Embodiments are described herein with reference to a cross-sectional view, a plan view, and/or a block diagram that are schematic illustrations of idealized embodiments and intermediate structures. In addition, in the drawings, the thicknesses of components may be exaggerated or omitted for clarity. Variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

The same reference numerals denote the same elements throughout the specification. Accordingly, the same numerals and similar numerals can be described with reference to other drawings, even if not specifically described in a corresponding drawing. Further, when a numeral is not marked in a drawing, the numeral can be described with reference to other drawings.

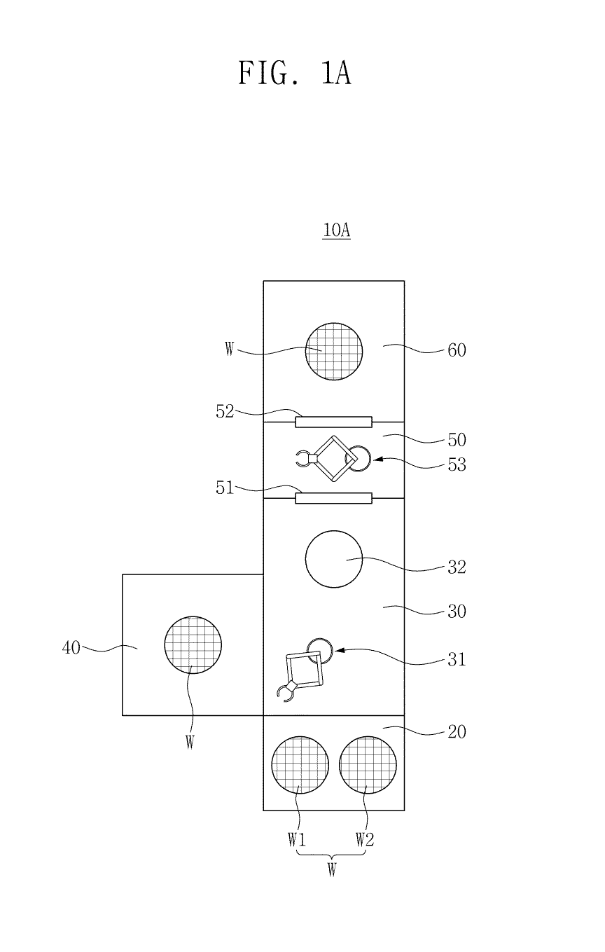

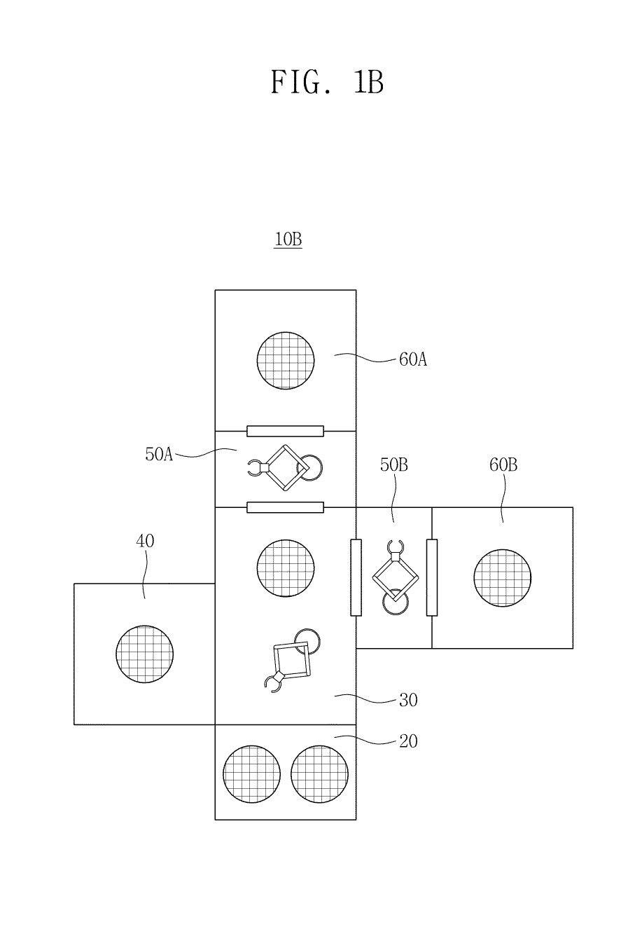

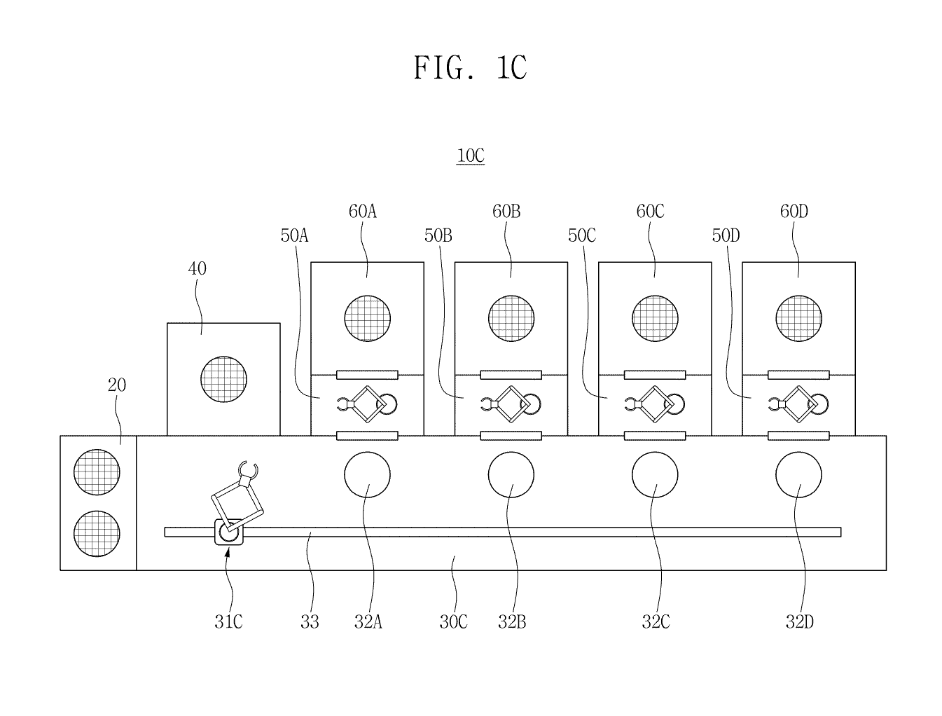

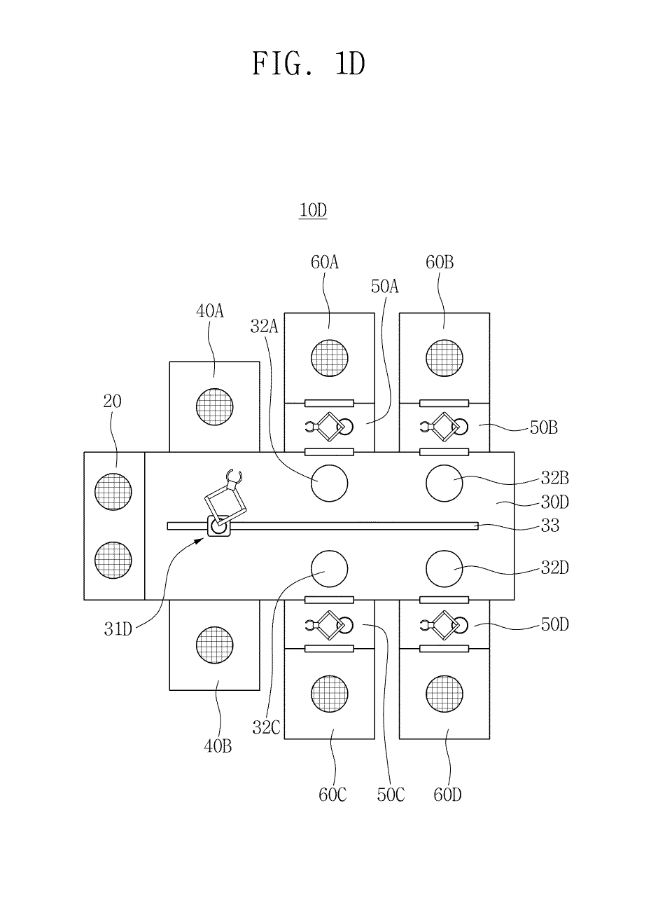

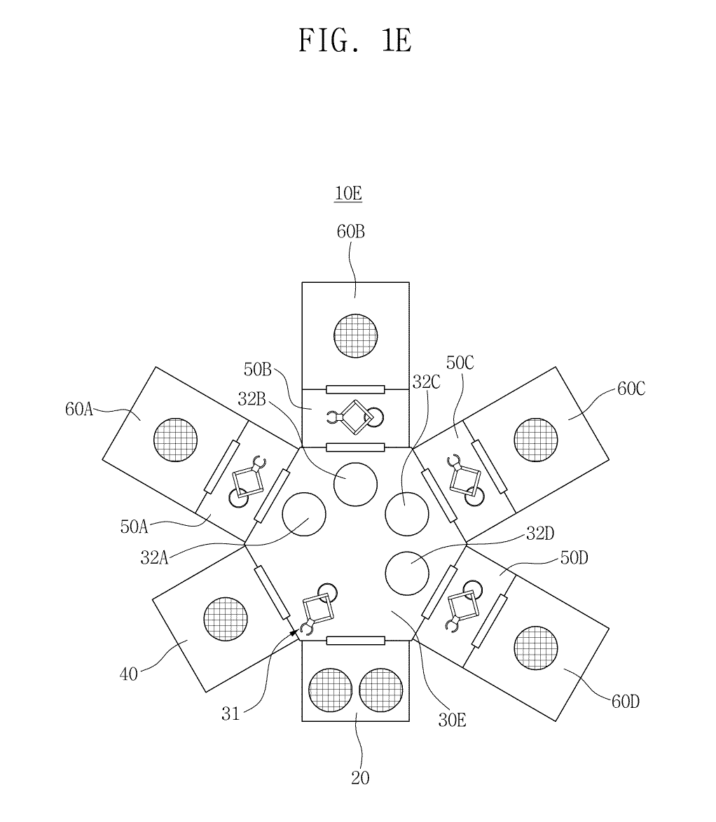

FIGS. 1A to 1E are block diagrams schematically illustrating inspecting apparatuses according to various embodiments.

Referring to FIG. 1A, an inspecting apparatus 10A according to an embodiment may include a wafer stocker 20, a transfer module 30, a laser anneal module 40, a buffer chamber 50, and an E-beam scanning module 60.

The wafer stocker 20 may have the shape of a shelf or a table. Semiconductor wafers W to be introduced into the inspecting apparatus 10A or semiconductor wafers W inspected in the inspecting apparatus 10A may be temporarily stocked on/in the wafer stocker 20.

The transfer module 30 may include a transfer arm 31 and/or a wafer station 32. The transfer arm 31 may load and transfer the semiconductor wafers W. For example, the transfer arm 31 may transfer the semiconductor wafers W disposed on/in the wafer stocker 20 to an inside of the laser anneal module 40, transfer the semiconductor wafers W from the laser anneal module 40 to the wafer station 32 or an inside of the buffer chamber 50, or transfer the semiconductor wafers W from the wafer station 32 or the inside of the buffer chamber 50 onto the wafer stocker 20. The wafer station 32 may be disposed in the transfer module 30 to be adjacent to the buffer chamber 50. A semiconductor wafer W1 to be inspected and a semiconductor wafer W2 inspected may be temporarily separated and stocked on the wafer station 32.

The buffer chamber 50 may include a sealable load-lock chamber. The buffer chamber 50 may adjust internal pressure from an atmospheric pressure state to a vacuum state or from a vacuum state to an atmospheric pressure state. The buffer chamber 50 may include an external door 51, an internal door 52, and a buffer transfer arm 53. The buffer transfer arm 53 may transfer the semiconductor wafer W from the transfer module 30 to an inside of the E-beam scanning module 60, or from the E-beam scanning module 60 to the transfer module 30.

For example, when the inside of the buffer chamber 50 is in the atmospheric pressure state, the external door 51 may be opened and the buffer transfer arm 53 may transfer the semiconductor wafer W from the wafer station 32 to the inside of the buffer chamber 50. Then, after the external door 51 is closed and the buffer chamber 50 is sealed and evacuated, the internal door 52 may be opened, the semiconductor wafer W may be transferred to the inside of the E-beam scanning module 60, and the buffer transfer arm 53 may move to the inside of the buffer chamber 50. Then, the internal door 52 may be closed to seal the inside of the E-beam scanning module 60.

After an E-beam scanning process is performed, the internal door 52 may be opened, the buffer transfer arm 53 may transfer the semiconductor wafer W disposed in the E-beam scanning module 60 to the inside of the buffer chamber 50. Then, the internal door 52 may be closed to seal the buffer chamber 50. After the vacuum state of the buffer chamber 50 is released, the external door 51 may be opened and the buffer transfer arm 53 may transfer the semiconductor wafer W onto the wafer station 32 of the transfer module 30.

The laser anneal module 40 and the E-beam scanning module 60 will be described later.

Referring to FIG. 1B, an inspecting apparatus 10B according to an embodiment, compared to the inspecting apparatus 10A of FIG. 1A, may include one laser anneal module 40 and a plurality of E-beam scanning modules 60A and 60B. Since time for performing an E-beam scanning process is much longer than time for performing a laser annealing process, the inspecting apparatus 10B may include one laser anneal module 40 and the plurality of E-beam scanning modules 60A and 60B. In addition, the inspecting apparatus 10B may include buffer chambers 50A and 50B, respectively for the E-beam scanning modules 60A and 60B.

Referring to FIG. 1C, an inspecting apparatus 10C according to an embodiment may include one laser anneal module 40 and a plurality of E-beam scanning modules 60A, 60B, 60C, and 60D disposed side by side on a first side of an elongated transfer module 30C, and a wafer stocker 20 disposed on a second side of the transfer module 30C. The transfer module 30C may include a transfer rail 33, a transfer arm 31C movable on the transfer rail 33, and a plurality of wafer stations 32A, 32B, 32C, and 32D. The transfer arm 31C may move along the transfer rail 33 and transfer the semiconductor wafers W to the wafer stocker 20, the laser anneal module 40, buffer chambers 50A, 50B, 50C, and 50D, the E-beam scanning modules 60, and the wafer stations 32A, 32B, 32C, and 32D.

Referring to FIG. 1D, an inspecting apparatus 10D according to an embodiment may include E-beam scanning modules 60A, 60B, 60C, and 60D disposed on both sides of the transfer module 30D. The inspecting apparatus 10D may further include a plurality of laser anneal modules 40A and 40B.

Referring to FIG. 1E, an inspecting apparatus 10E according to an embodiment may have a cluster shape. For example, the inspecting apparatus 10E may include a wafer stocker 20, a laser anneal module 40, buffer chambers 50A, 50B, 50C, and 50D, and E-beam scanning modules 60A, 60B, 60C, and 60D, radially disposed around a transfer module 30E disposed in a center portion.

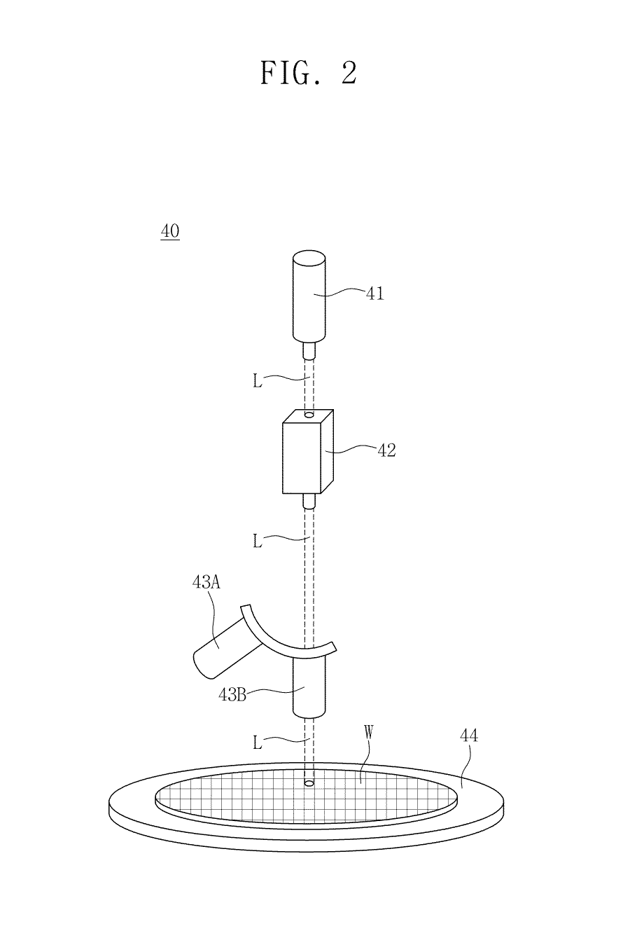

FIG. 2 is a diagram schematically illustrating a laser anneal module of an inspecting apparatus according to an embodiment. Referring to FIG. 2, a laser anneal module 40 of the inspecting apparatus according to the embodiment may include a laser source 41, an attenuator 42, objective lenses 43A and 43B, and a stage 44.

The laser source 41 may include a laser oscillator. The laser oscillator may include one of a Nd:YAG laser, a Nd:YVO₄ laser, a Nd:YLF laser, a Ti:sapphire laser, a He:Ne laser, an IR laser, a green laser, a blue laser, and other various lasers.

The attenuator 42 may adjust energy or amplitude of a laser beam L generated in the laser source 41. The attenuator 42 may include a wavelength converter, a beam shaper, or a shutter. For example, the wavelength converter may uniformize a wavelength of the laser beam L, the beam shaper may form a shape of the laser beam L, and the shutter may output the laser beam L in the form of a continuous wave (CW) or a pulse.

The objective lenses 43A and 43B may have various numerical apertures NAs. Thus, the objective lenses 43A and 43B may variously adjust a beam size of the laser beam L so as to variously define a size of an area which is irradiated by the laser beam L on the semiconductor wafer W in the range of several tens to several hundreds of nanometers. The objective lenses 43A and 43B may be rotated and arranged in a path of the laser beam L.

The semiconductor wafer W may be mounted on the stage 44. The stage 44 may move in up and down, back and forth, and left and right.

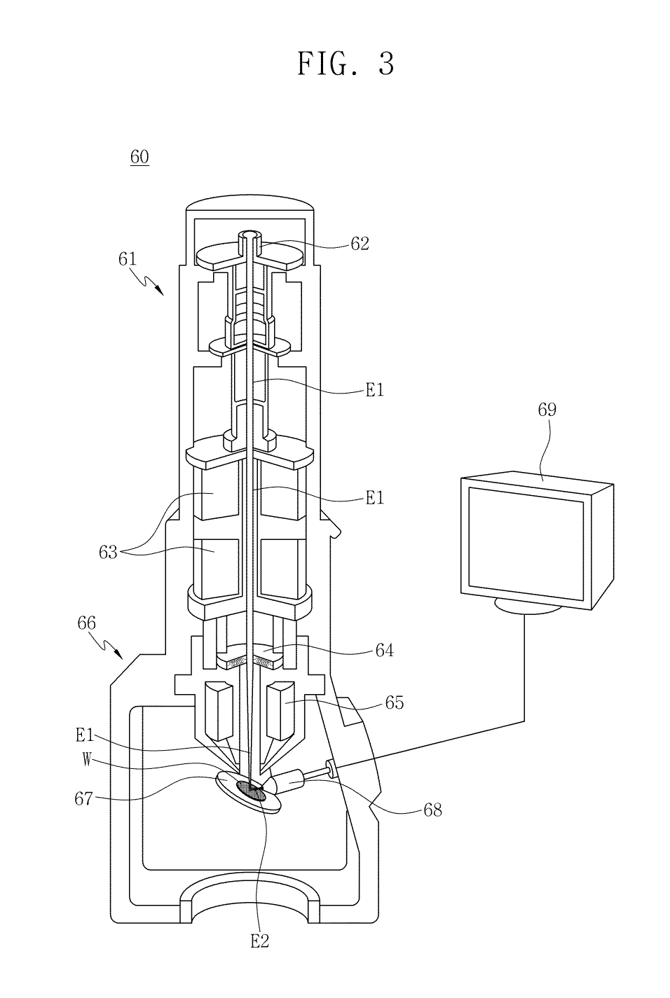

FIG. 3 is a diagram schematically illustrating an E-beam scanning module of an inspecting apparatus according to an embodiment. Referring to FIG. 3, an E-beam scanning module 60 of the inspecting apparatus according to the embodiment may include an E-beam gun 62, a condenser lens 63, a scanning coil 64, a body 61 having an objective lens 65, a chamber 66 having a stage 67 and an electron collector 68, and a display 69.

The body 61 may have a tube shape. The chamber 66 may be combined to the body 61 to be located under the body 61. Both insides of the body 61 and the chamber 66 may be evacuated.

The E-beam gun 62 may emit an E-beam E1. The condenser lens 63 may adjust a propagation path of the E-beam E1 so that the E-beam E1 is straight without departing from the path. The condenser lens 63 may form an electric field and a magnetic field.

The scanning coil 64 may swing the E-beam E1 back and forth within a predetermined range. The E-beam E1 may be radiated on the semiconductor wafer W in a segment form depending on the scanning coil 64.

The objective lens 65 may focus the E-beam E1 to be radiated on the semiconductor wafer W. The objective lens 65 may also form an electric field and a magnetic field.

The semiconductor wafer W may be mounted on the stage 67. The stage 67 may move in up and down, back and forth, and left and right.

The electron collector 68 may collect secondary electrons E2 emitted from the semiconductor wafer W or recoiled electrons.

The display 69 may include a monitor. The display 69 may display a visual image on the monitor according to the amount of the secondary electrons E2 collected by the electron collector 68. The visual image may include a gray-scale image.

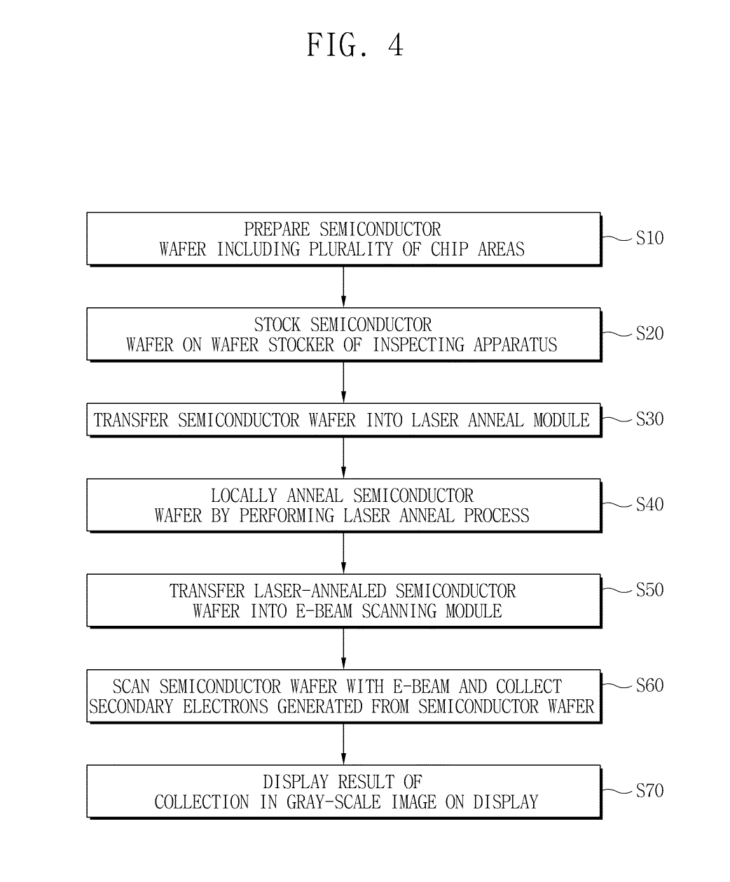

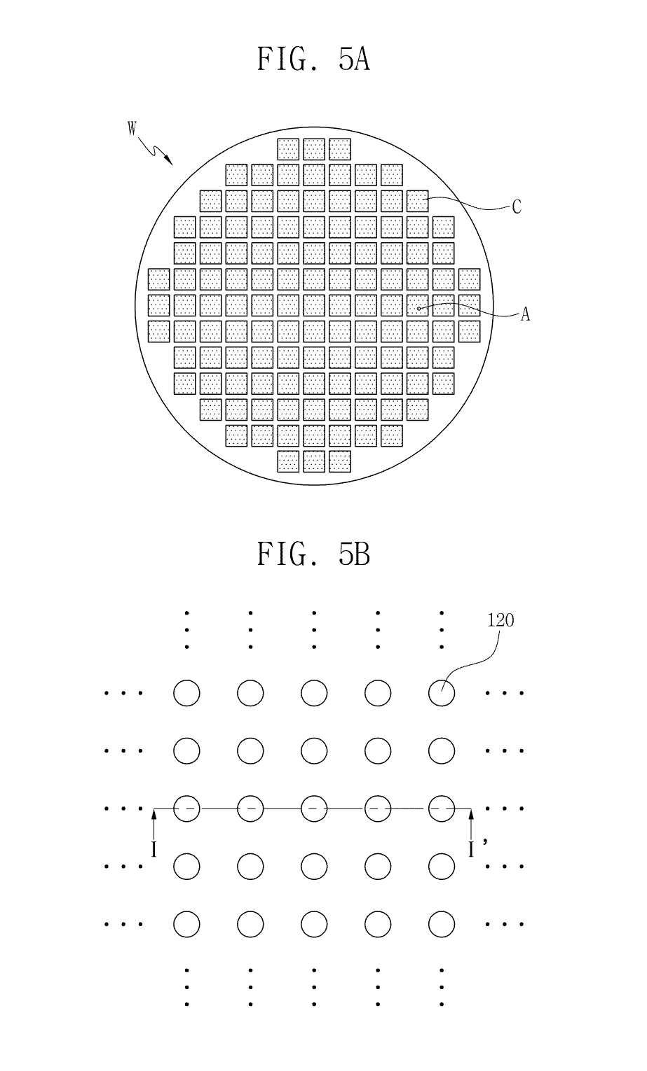

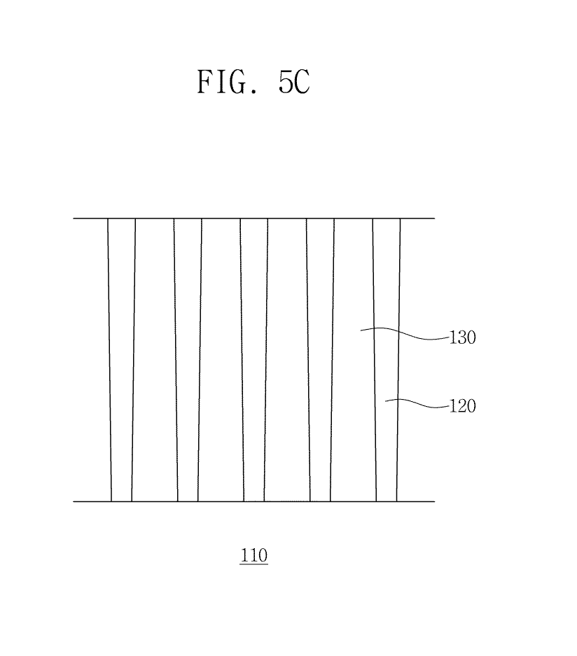

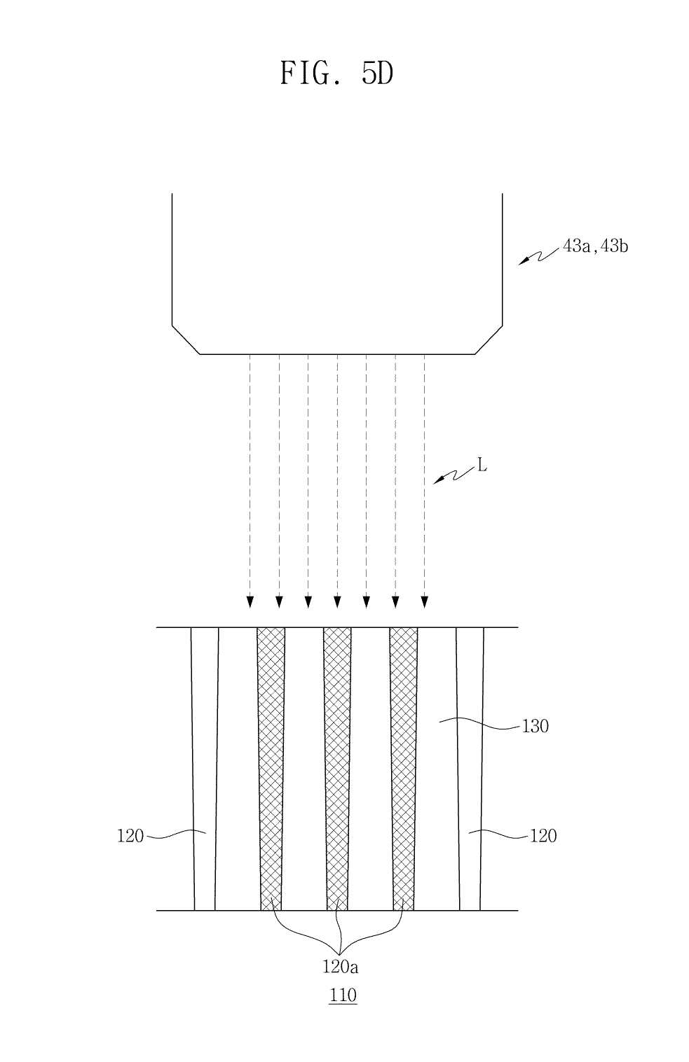

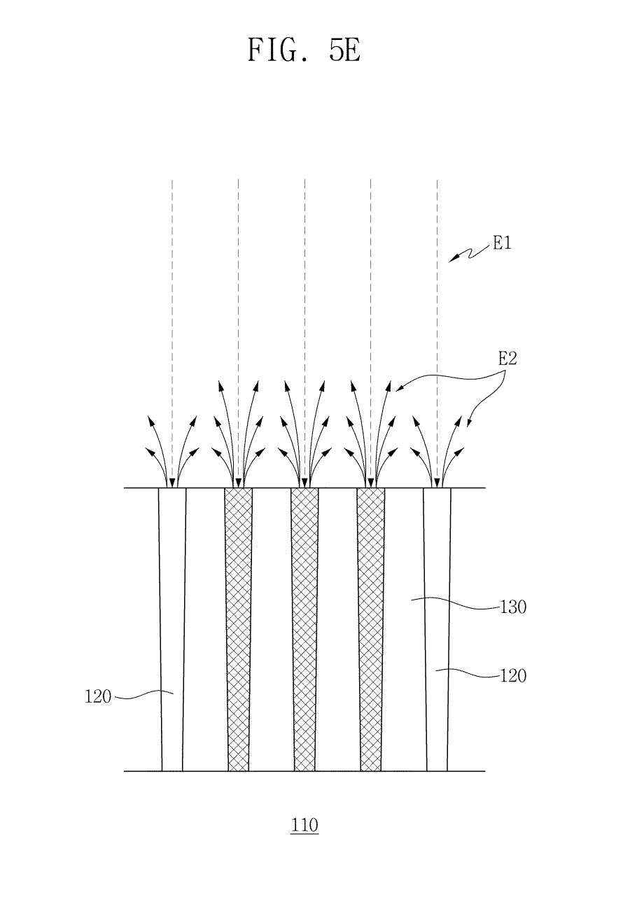

FIG. 4 is a flowchart for describing a method of inspecting resistive defects of contact plug patterns of a semiconductor device according to an embodiment. FIGS. 5A to 5E are diagrams for describing a method of inspecting resistive defects of contact plug patterns of a semiconductor device according to an embodiment.

Referring to FIGS. 4 and 5A, the method of inspecting a resistive defect of contact plug patterns of a semiconductor device according to the embodiment may include preparing a semiconductor wafer W including a plurality of chip areas C (S10). The semiconductor wafer W may include one of a single-crystalline silicon layer, a silicon epitaxial layer, a poly-crystalline silicon layer, or an amorphous silicon layer.

FIG. 5B is an enlarged view of the area A of FIG. 5A. Referring to FIG. 5B, the chip area C of the semiconductor wafer W may include a plurality of contact plug patterns 120. In the drawing, the contact plug patterns 120 are uniformly arranged in a grid form, but the arrangement is only illustrative. The contact plug patterns 120 may be irregularly arranged alone, in pairs, in the form of vertices of a polygon, in a string formed as a horizontal or vertical column, or in a group formed of a plurality of clusters.

FIG. 5C is a vertical cross-sectional view taken along line I-I! of FIG. 5B. Referring to FIG. 5C, the contact plug patterns 120 may be directly formed on a lower layer 110 to be in contact with the lower layer 110. Side surfaces of the contact plug patterns 120 may be surrounded by an insulating layer 130. The lower layer 110 may include a semiconductor substrate and a conductive material formed on the semiconductor substrate. For example, the conductive material may include a metal, a metal silicide, a metal compound, single-crystalline silicon, or poly-crystalline silicon. The contact plug patterns 120 may include poly-crystalline silicon or amorphous silicon. For example, the lower layer 110 and the contact plug patterns 120 may include the same material to be materially continuous. The insulating layer 130 may include silicon oxide or silicon nitride.

Referring to FIGS. 1A to 1E, and FIG. 4, the method may include stocking the semiconductor wafer W on the wafer stocker 20 of the inspecting apparatus 10 (S20).

Referring to FIGS. 1A to 1E, and FIG. 4, the method may include transferring the semiconductor wafer W disposed on the wafer stocker 20 into the laser anneal module 40 using the transfer arm 31 of the transfer module 30 (S30). The inside of the laser anneal module 40 may be at atmospheric pressure.

Referring to FIGS. 2, 4, and 5D, the method may include performing a laser anneal process in the laser anneal module 40 to locally anneal the contact plug patterns 120 formed in portions of the semiconductor wafer W (S40). The laser anneal process may include irradiating a local area of the semiconductor wafer W with a laser beam L from the objective lens 43a and 43b of the laser anneal module 40. The laser anneal process may include selectively annealing an area which needs to be inspected, without radiating and heating the entire semiconductor wafer W. By the laser anneal process, the contact plug patterns 120 irradiated with the laser beam L may be crystallized. For example, the contact plug patterns 120 may be transitioned to a crystallized state or a more advanced crystallization state, for example, from a poly-crystalline silicon state or an amorphous silicon state to a single-crystalline silicon state or a poly-crystalline silicon state.

The laser anneal process may be variously split. For example, the laser anneal process may include irradiating the semiconductor wafer W with the laser beam L having variously split energy. Accordingly, the contact plug patterns 120 may be crystallized to various levels depending on the energy of the radiated laser beam L. The annealed contact plug patterns 120a may have various types of carrier mobility depending on the level of crystallization.

The area of the semiconductor wafer W on which the laser beam L is radiated may be heated to a temperature of about 600 to 850° C. to crystallize the contact plug patterns 120.

Referring to FIGS. 1A to 1E, and FIG. 4, the method may include transferring the locally laser-annealed semiconductor wafer W to the inside of the E-beam scanning module 60 (S50). For example, the transfer arm 31 of the transfer module 30 may transfer the locally laser-annealed semiconductor wafer W onto the wafer station 32, the buffer transfer arm 53 disposed in the buffer chamber 50 may transfer the locally laser-annealed semiconductor wafer W disposed on the wafer station 32 to the inside of the buffer chamber 50, the buffer chamber 50 may be sealed and evacuated, a path between the buffer chamber 50 and the E-beam scanning module 60 may open, and the buffer transfer arm 53 may transfer the laser-annealed semiconductor wafer W to the inside of the E-beam scanning module 60 and mount the laser-annealed semiconductor wafer W on the stage 67. The buffer chamber 50 may be changed from an atmospheric pressure state to a vacuum state, and the inside of the E-beam scanning module 60 may be in the vacuum state.

Referring to FIGS. 3, 4, and 5E, the method may include scanning the laser-annealed semiconductor wafer W with an E-beam E1 and collecting secondary electrons E2 generated from the semiconductor wafer W by performing an E-beam scanning process and a collecting process (S60).

The E-beam scanning process may be performed such that the amount of the secondary electrons E2 is greater than the amount of electrons of the injected E-beam E1. The secondary electrons E2 may be generated mainly from the contact plug patterns 120. The secondary electrons E2 may be differently collected depending on levels of carrier mobility of the contact plug patterns 120. For example, when the contact plug patterns 120 have high carrier mobility, a greater number of secondary electrons E2 may be generated and collected, and when the contact plug patterns 120 have low carrier mobility, a lesser number of secondary electrons E2 may be generated and collected. For example, when the secondary electrons E2 are generated and collected in the electron collector 68 of the E-beam scanning module 60, a potential difference may occur in the contact plug patterns 120. For example, the potential difference may occur due to the difference in concentration of electrons existing in the contact plug patterns 120 and the lower layer 110. Due to the potential difference, electrons may be supplied from the lower layer 110 to the contact plug patterns 120. Accordingly, since relatively more electrons are supplied from the lower layer 110 when the contact plug patterns 120 have high carrier mobility, the contact plug patterns 120 having high carrier mobility may emit relatively more secondary electrons E2.

Accordingly, the difference in electrical conductivity of the contact plug patterns 120 may result in an amplified result according to some of the embodiments.

Next, the method may include displaying the result of inspection in a gray-scale image on the display 69 (S70).

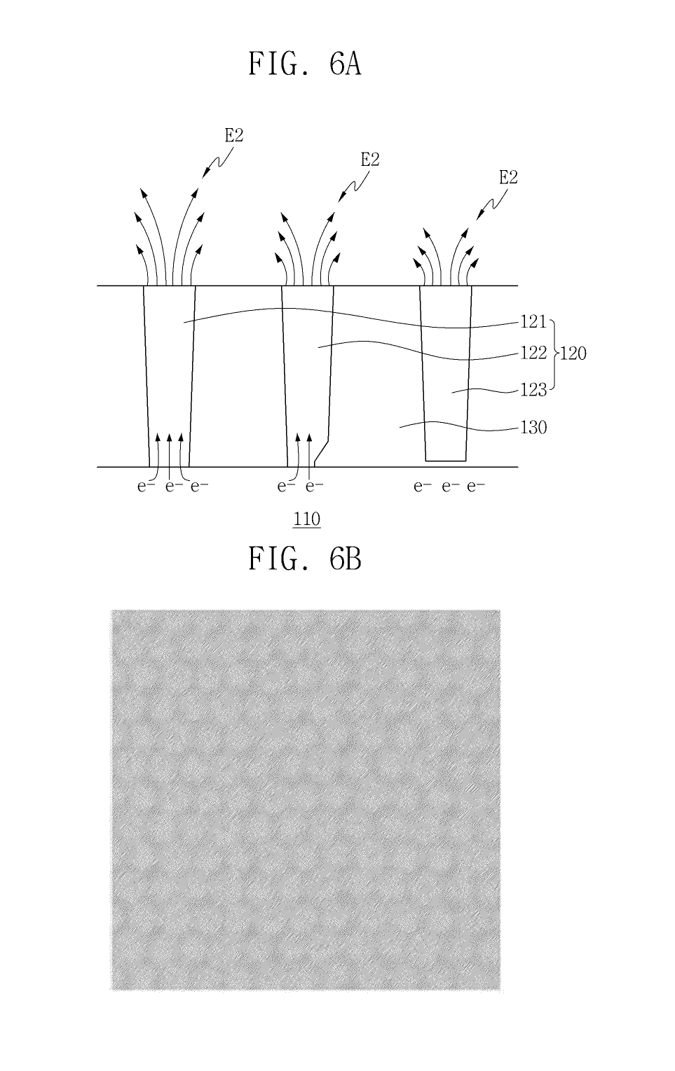

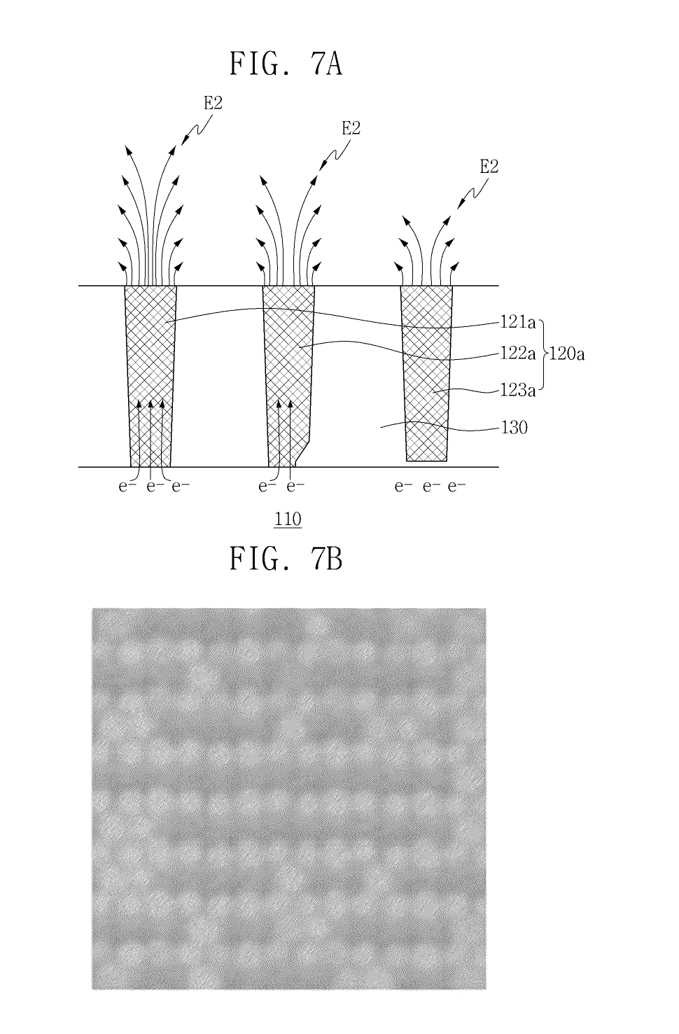

FIGS. 6A and 6B are a diagram and a SEM photograph illustrating secondary electrons E2 emitted from contact plug patterns which are not laser-annealed, and FIGS. 7A and 7B are a diagram and a SEM photograph illustrating secondary electrons E2 emitted from laser-annealed contact plug patterns.

Referring to FIGS. 6A and 6B, the amount of secondary electrons E2 emitted from the contact plug patterns 120 which are not laser-annealed, may not be significantly different between an open state and a not-open state.

Referring to FIGS. 7A and 7B, the amount of secondary electrons E2 emitted from the laser-annealed contact plug patterns 120a may be amplified according to an open or not-open state and be relatively and significantly different.

Depending on a contact area between the contact plug patterns 120 and 120a and the lower layer 110, the contact plug patterns 120 and 120a may have different electrical resistance values. Accordingly, the amount of electrons supplied from the lower layer 110 to the contact plug patterns 120 and 120a may differ depending on the contact resistance values between the contact plug patterns 120 and 120a and the lower layer 110. For example, the contact plug patterns 120 and 120a formed in fully-open contact holes and electrically fully connected to the lower layer 110 among the contact plug patterns 120 and 120a may emit sufficient secondary electrons E2 since electrons are sufficiently supplied from the lower layer 110. The contact plug patterns 120 and 120a formed in partially-open contact holes and electrically partially connected to the lower layer 110 among the contact plug patterns 120 and 120a may partially and limitedly emit secondary electrons E2 since electrons are partially and limitedly supplied from the lower layer 110. The contact plug patterns 120 and 120a formed in not-open contact holes and electrically disconnected to the lower layer 110 among the contact plug patterns 120 and 120a may emit a small amount of secondary electrons E2 since electrons are not supplied from the lower layer 110. Accordingly, the emission amount of the secondary electrons E2 may differ depending on open/not-open conditions of the contact holes and, more specifically, depending on states of electrical and physical connection between the contact plug patterns 120 and 120a and the lower layer 110.

According to some of the embodiments, since electrical resistances of the laser-annealed contact plug patterns 120a are low, free electrons may more easily move from the lower layer 110 to the contact plug patterns 120 and 120a. Accordingly, not only open/not-open conditions of the contact plug patterns 120 and 120a but also a more difference in electrical resistances of the contact plug patterns 120 and 120a may be shown.

According to some of the embodiments, productivity of a semiconductor device may be improved. Since a coil-type heater or a halogen lamp is used in a process of annealing the entire semiconductor wafer W and inspecting the annealed semiconductor wafer W, a long process time for annealing the semiconductor wafer W may be required. In addition, productivity may be lowered since an inspected semiconductor wafer W is eliminated. According to some of the embodiments, a process time may be very short since only a part of the semiconductor wafer W is heated using a laser. In addition, since only a locally annealed portion of the semiconductor wafer W is eliminated, the other portions of the semiconductor wafer W may be used as a normal product.

According to some of the embodiments, since a resistive defect of a semiconductor device may be detected as an amplified result, inspection may be more precise.

According to some of the embodiments, only a part (parts of chips) of a semiconductor wafer may be consumed since the part of the semiconductor wafer is annealed and scanned with E-beam. According to some of the embodiments, the amount of time spent on the inspection process may be reduced by using an integrated inspecting apparatus. Accordingly, productivity may increase and product costs may decrease.

Although a few embodiments have been described, those skilled in the art will readily appreciate that many modifications are possible without materially departing from the novel teachings and advantages. Accordingly, all such modifications are intended to be included within the scope of this inventive concepts as defined in the claims.

What is claimed is:

1. A method of inspecting a resistive defect of a semiconductor device, comprising:
loading a semiconductor wafer on a wafer stocker;
transferring the semiconductor wafer into a laser anneal module using a transfer module;
annealing a portion of the semiconductor wafer using a laser beam in an atmospheric pressure;
transferring the annealed semiconductor wafer into an E-beam scanning module using the transfer module;
scanning the annealed portion of the semiconductor wafer with an E-beam in a vacuum; and
collecting secondary electrons emitted from the annealed portion of the semiconductor wafer.

2. The method of claim 1, wherein the transfer module includes a transfer arm, and the transfer arm transfers the semiconductor wafer loaded on the wafer stocker into the laser anneal module.

3. The method of claim 2, wherein the transfer module further comprises a wafer station disposed adjacent to the E-beam scanning module, and
the transfer arm transfers the semiconductor wafer from the inside of the laser anneal module onto the wafer station.

4. The method of claim 3, wherein the transfer arm transfers the semiconductor wafer disposed on the wafer station onto the wafer stocker.

5. The method of claim 4, wherein the transfer module further comprises a transfer rail, and
the transfer arm moves along the transfer rail.

6. The method of claim 1, wherein the laser anneal module comprises a laser source, an attenuator, a plurality of objective lenses, and a stage,
the attenuator adjusts energy of a laser beam generated from the laser source, and the plurality of objective lenses have various apertures.

7. The method of claim 1, wherein the transferring of the annealed semiconductor wafer into the E-beam scanning module comprises:
transferring the annealed semiconductor wafer into a buffer chamber;
sealing and evacuating the buffer chamber; and
transferring the annealed semiconductor wafer into the E-beam scanning module.

8. The method of claim 7, wherein the buffer chamber includes a buffer transfer arm, and
the buffer transfer arm transfers the annealed semiconductor wafer into the buffer chamber and transfers the annealed semiconductor wafer into the E-beam scanning module.

9. The method of claim 1, wherein the E-beam scanning module comprises:
a tube-type body including an E-beam gun, a condenser lens, a scanning coil, and an objective lens;
a chamber including a stage and an electron collector; and
a display,
wherein the display visually displays the amount of the collected secondary electrons on a monitor.

10. The method of claim 1, wherein the amount of secondary electrons emitted from the annealed portion is greater than the amount of the E-beam injected into the annealed portion.

11. A method of inspecting a resistive defect of a semiconductor device, comprising:
providing a semiconductor wafer including contact plug patterns;
locally annealing portions of the semiconductor wafer to crystallize the contact plug patterns;
scanning the crystallized contact plug patterns with an E-beam; and
collecting secondary electrons emitted from the contact plug patterns scanned with the E-beam.

12. The method of claim 11, wherein the contact plug patterns include poly-crystalline silicon.

13. The method of claim 12, wherein the contact plug patterns are formed on a lower layer to be in direct contact with the lower layer, and
the lower layer includes one of a metal, a metal silicide, a metal compound, single-crystalline silicon, poly-crystalline silicon, and any combination thereof.

14. The method of claim 11, wherein the locally annealing of the semiconductor wafer includes irradiating the contact plug patterns disposed on the portions of the semiconductor wafer with a laser beam.

15. The method of claim 14, wherein the locally annealing of the semiconductor wafer includes heating the contact plug patterns to a temperature of 600 to 800° C.

16. A method of inspecting a resistive defect of a semiconductor device, comprising:
providing an inspecting apparatus including a wafer stocker, a transfer module, an annealing module, a buffer chamber, and an E-beam scanning module;
loading a semiconductor wafer including contact plug patterns on the wafer stocker;
transferring the semiconductor wafer into the annealing module using a transfer arm of the transfer module;
locally annealing portions of the semiconductor wafer in the annealing module to crystallize the contact plug patterns;
transferring the semiconductor wafer into the buffer chamber;
evacuating the buffer chamber;
transferring the semiconductor wafer disposed in the buffer chamber into the E-beam scanning module;
scanning the locally-crystallized contact plug patterns of the semiconductor wafer with an E-beam in the E-beam scanning module;
collecting secondary electrons from the locally-crystallized contact plug patterns; and
displaying a gray-scale image of the contact plug patterns on a monitor according to the amount of the collected secondary electrons.

17. The method of claim 16, wherein the locally annealing of the semiconductor wafer includes irradiating the portions of the semiconductor wafer with a laser beam.

18. The method of claim 16, wherein transferring of the crystallized semiconductor wafer into the buffer chamber comprises:
transferring the crystallized semiconductor wafer onto a wafer station disposed adjacent to the buffer chamber in the transfer module and stacking the crystallized semiconductor wafer by the transfer arm of the transfer module; and
transferring the semiconductor wafer disposed on the wafer station into the buffer chamber by a buffer transfer arm in the buffer chamber.

19. The method of claim 16, wherein the evacuating of the buffer chamber comprises:
transferring the crystallized semiconductor wafer into the buffer chamber; and
sealing the inside of the buffer chamber by closing an external door and an internal door.

20. The method of claim 16, further comprising:
transferring the semiconductor wafer disposed in the E-beam scanning module into the buffer chamber using the buffer transfer arm;
sealing the inside of the buffer chamber and adjusting a pressure of the inside of the buffer chamber to atmospheric pressure; and
transferring the semiconductor wafer disposed in the buffer chamber onto the wafer stocker.
